(19) United States
(12) Patent Application Publication
(10) Pub. No.: US 2015/0327384 A1
(43) Pub. Date: Nov. 12, 2015

(54) ELECTRONIC DEVICE

(71) Applicants: SANYO Technology Center (Shenzhen) Co., Ltd., Shenzhen City, Guangdong Province (CN); SANYO ELECTRIC CO., LTD., Moriguchi City, Osaka Prefecture (JP)

(72) Inventors: RONGFA CHEN, Shenzhen City, Guangdong Province (CN); JIDONG MAO, Shenzhen City, Guangdong Province (CN); KEMING LIU, Shenzhen City, Guangdong Province (CN); JIANMING XIAO, Shenzhen City, Guangdong Province (CN); SHINYA YAMAMOTO, Moriguchi City, Osaka Prefecture (JP); NOBUYUKI TAKE, Moriguchi City, Osaka Prefecture (JP)

(21) Appl. No.: 14/423,433

(22) PCT Filed: Jul. 9, 2013
(86) PCT No.: PCT/CN2013/079073

§ 371 Date: Feb. 23, 2015

(51) Int. Cl. H05K 5/02

(52) U.S. Cl. CPC H05K 5/0234

(57) ABSTRACT

The present application discloses an electronic device, which comprises a main body and a base with which the main body is capable of seating upon a surface of a table, wherein the base includes a base body and a lug boss fixed on the base body; the lug boss is provided with a first inserting component, and a second inserting component adapted to the first inserting component is provided on the bottom of the main body; the first inserting component and the second inserting component are plugged into each other for connecting the main body to the base. The assembly is simply without using screws for fixation; the appearance is aesthetic; a height of the base and the space for placing the base are reduced, a weight of the package is lightened; the number of the components of the base is decreased.

### BACKGROUND OF THE INVENTION

1. Field of the Invention

The present application relates to the field of electronic products, and more particularly to an electronic device.

2. The Related Arts

With the scientific advancement and the economic development, more and more electronic devices, such as flat panel televisions or liquid crystal displays (LCDs) of desktop computers are brought into people's daily life.

Take the flat panel television as an example, the flat panel television in the prior art, may be hung on a wall, or seated upon a table. For the flat panel television hung on a wall, the flat panel television is generally hooked onto a hanger which is fixed on a wall; while for the flat panel television seated upon a table, a base is generally equipped, which is arranged on the bottom of the flat panel television, in such a way that the flat panel television is possible to be put on a table by means of the base.

A base 92 of a flat panel television 91 is structurally illustrated in FIG. 1, FIG. 2 and FIG. 3. FIG. 1 structurally shows a situation that the base 92 is arranged on the flat panel television 91, FIG. 2 illustrates the structure of the flat panel television 91, and FIG. 3 shows the structure of the base 92. As shown in FIG. 3, the base 92 comprises a mounting seat 93, on which a mounting plate 94 is fixed. An extension portion 95 is fixed on the mounting plate 94, and a plurality of mounting holes 96 are defined in the extension portion 95. As shown in FIG. 2, a notch 97 is defined on the bottom of the back of the flat panel television 91, and positioning holes 98 matching with the mounting holes 96 are defined in the notch 97. As shown in FIG. 1, when in use, the extension portion 95 is mounted in the notch 97, the mounting holes 96 and the positioning holes 98 are in one-to-one correspondence, and a fastening element (such as a screw) runs through a mounting hole 96 and a corresponding positioning hole 98 to fix the mounting hole and the positioning hole, so that the base 92 is possible to be arranged on the flat-panel television 91.

However, the base 92 in the prior art has a lot of defects which are described as follows.

1. During the manufacture of the electronic device, the base 92 needs to be arranged on the electronic device when the electronic device needs to be in a standing state in some cases. However, there may be a plurality of screws to deal with during the assembly and disassembly of the base 92, and thus the production efficiency is low.

2. When the electronic device is put on a table, since there are also a plurality of screws to install during the assembly of the base 92, it is a complex operation for the user to mount the base 92.

3. The configuration of the notch 97 defined on the back of the electronic device and matched with the extension portion 95 of the base 92 may influence the optimizations and aesthetics of the appearance. The neck (the mounting plate 94 and the extension portion 95) of the base 92 is comparatively long, and it may affect the placement of the base 92 during the packaging process, thereby causing a larger packaging size.

4. The structure of the base 92 is relatively complex, a production cost is high, and a production assembly is poor.

Therefore, there are a lot of defects in the prior art, and improvements are needed.

### SUMMARY OF THE INVENTION

To overcome the defects in the prior art, the object of the present application is to provide an electronic device which has a simply assembly and an aesthetic appearance.

The technical solution of the application is as follows: In one aspect, an electronic device is provided, which comprises a main body and a base with which the main body is capable of seating upon a surface of a table, wherein the base includes a base body and a lug boss fixed on the base body. The lug boss is provided with a first inserting component, and a second inserting component adapted to the first inserting component is provided on the bottom of the main body. The first inserting component and the second inserting component are plugged into each other for connecting the main body to the base.

In one embodiment, the first inserting component includes a first engaging element, and the second inserting component includes a second engaging element; the first engaging element is engaged with the second engaging element.

In a further embodiment, the first engaging element includes a buckle, and the second engaging element includes a buckle slot; the buckle is inserted into the buckle slot and is engaged with the buckle slot.

In a further embodiment, the buckle includes an abutting portion arranged in the buckle slot and an engaging portion horizontally extending from an end of the abutting portion.

In a further embodiment, the first inserting component further includes a first positioning element, the second inserting component includes a first positioning slot, and the first positioning element is sheathed in the first positioning slot.

In a further embodiment, the first inserting component includes a second positioning slot, and the second inserting component includes a second positioning element; the second positioning element is sheathed in the second positioning slot.

In a further embodiment, a groove adapted to the lug boss is formed on the bottom of the main body, and the groove includes a bottom wall, on which both the second engaging element and the first positioning slot are arranged.

In a further embodiment, the lug boss includes a top surface and a plurality of lateral surfaces extending around a circumference of the top surface in the same direction, a cavity is formed by the top surface and the plurality of lateral surfaces, and the first engaging element and the first positioning element are arranged on the top surface.

In a further embodiment, the base body, the lug boss, the first engaging element and the first positioning element are integrally formed with each other.

In a further embodiment, a through hole communicated with the cavity is defined on the base body.

In a further embodiment, the first positioning element includes a resilient inserting portion positioned in the first positioning slot and a pressing handle extending along the resilient inserting portion in the direction towards the through hole, wherein the pressing handle is arranged in the cavity.

By implementing the electronic device of the present application, the following advantages can be achieved: the base may be directly arranged on the main body, without using screws for the fixation, and the assembly is simply; no notch adapted to the base is defined on the back of the main body, in such a way that the appearance optimization may be facilitated, and the appearance of the main body is aesthetic; a height of the base is reduced, which helps to reduce the space for placing the base, further lighten a weight of the package, and simplify the placement of the base; the simple structure decreases the number of the components of the base, reduces the costs and improves the production efficiency.

### BRIEF DESCRIPTION OF THE DRAWINGS

The present application will be further described with reference to the accompanying drawings and embodiments in the following, in the accompanying drawings:

FIG. 1 structurally illustrates a situation that a base is arranged on a flat panel television in the prior art;

FIG. 2 illustrates a structure of the flat panel television shown in FIG. 1;

FIG. 3 illustrates a structure of the base shown in FIG. 1;

FIG. 4 illustrates a structure of an electronic device in accordance with an embodiment of the present application;

FIG. 5 illustrates a structure of the main body shown in FIG. 4;

FIG. 6 illustrates a structure of the base body and the lug boss in FIG. 4;

FIG. 7 illustrates a bottom view of FIG. 4;

FIG. 8 illustrates a cutaway view of FIG. 7 along line A-A;

FIG. 9 illustrates a partially enlarged view of part C of FIG. 8;

FIG. 10 illustrates a cutaway view of FIG. 7 along line B-B; and

FIG. 11 illustrates a partially enlarged view of part D of FIG. 10.

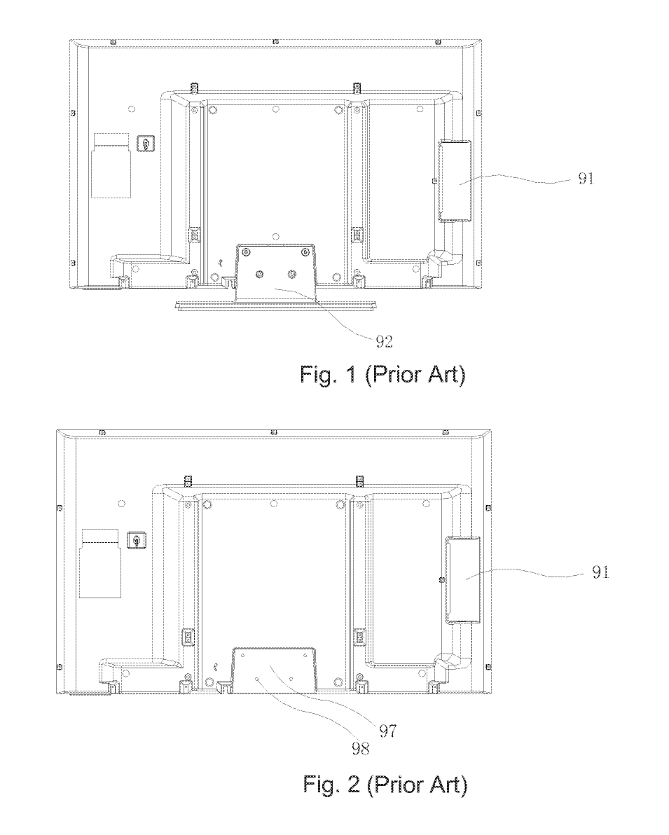

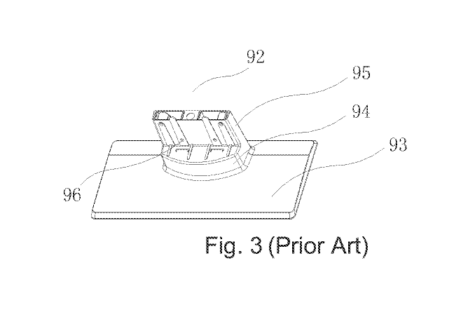

In FIGS. 1-3:

91-flat panel television, 92-base, 93-mounting seat, 94-mounting plate, 95-extension portion, 96-mounting hole, 97-notch, 98-positioning hole

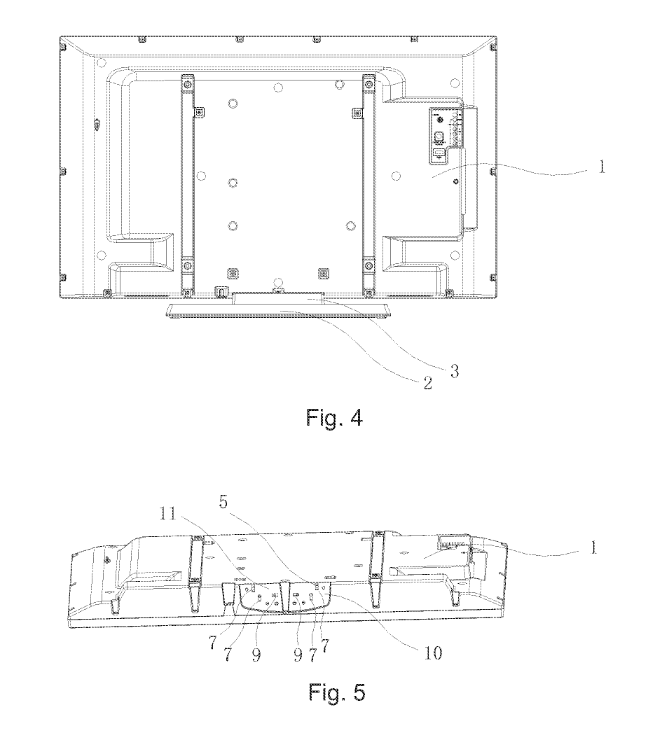

In FIG. 4-FIG. 11:

1-main body, 2-base body, 3-lug boss, 4-first engaging element, 5-second engaging element, 6-buckle, 7-buckle slot, 8-first positioning element, 9-first positioning slot, 10-groove, 11-bottom wall;

21-through hole, 31-top surface, 32-lateral surface, 33-cavity, 61-abutting portion, 62-engaging portion, 81-resilient inserting portion, 82-pressing handle.

### DETAILED DESCRIPTION OF THE PREFERRED EMBODIMENTS

To make the objects, the technical solution and the advantages of the present application more clearly understood, the present application is to be further described with reference to the accompanying drawings and embodiments.

### Embodiment 1

Referring to FIGS. 4-6, an electronic device is provided, which comprises a main body 1 and a base with which the main body 1 is capable of seating upon a surface of a table. The base includes a base body 2 and a lug boss 3 fixed on the base body 2, wherein the lug boss 3 is provided with a first inserting component. A second inserting component adapted to the first inserting component is provided on the bottom of the main body 1, wherein the first inserting component and the second inserting component are plugged into each other, for connecting the main body 1 to the base.

In this embodiment, the first inserting component comprises a first engaging element 4 and a first positioning element 8, while the second inserting component comprises a second engaging element 5 and a first positioning slot 9. The first engaging element 4 is engaged with the second engaging element 5, and the first positioning element 8 is sheathed in the first positioning slot 9. Herein, the first engaging element 4 includes a buckle 6, and the second engaging element includes a buckle slot 7. Specific structure will be further described in detailed as follows.

The main body 1 is not limited to a flat panel television (such as a LCD flat panel television) which may be any conventional flat panel television in the prior art, and the size of the flat panel television is also not limited here. For example it can be 14 inch, 26 inch, 32 inch, 42 inch, or 49 inch, etc. In some embodiments, the main body 1 may be a LCD screen of a desktop computer or other kinds of electronic devices. As shown in FIG. 5, the bottom of the main body 1 refers to the lowest region of the main body 1 in regular use, or refers to a lateral surface of the main body 1 that is underneath the main body 1 and opposite to the surface of the table.

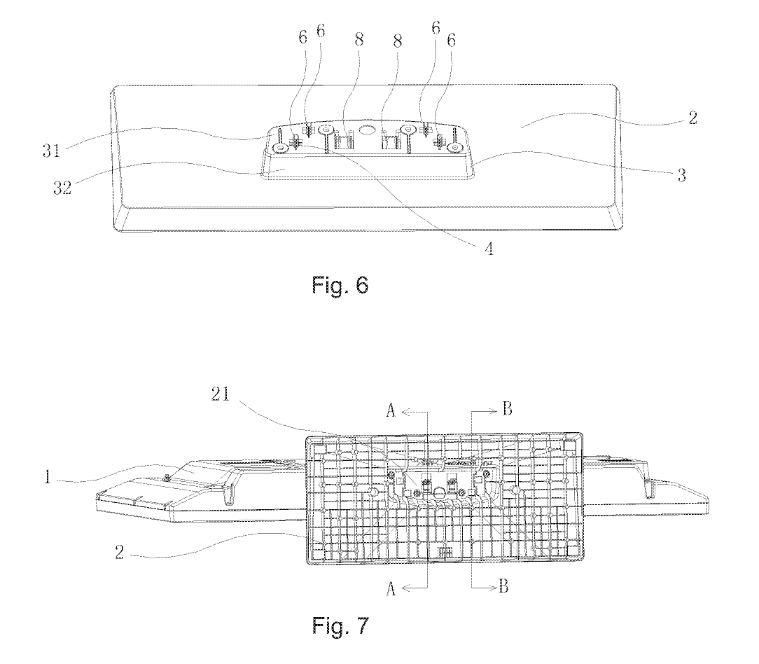

As show in FIG. 6, the main body 2 may be designed in shape of a rectangle, a square or a trapezoid, or in other shapes as required. In this embodiment, the main body 2 is in shape of a rectangular.

Preferably, the lug boss 3 is fixed on the main body 2, and is further integrated with the main body 2. In this way, not only the production efficiency can be improved, but also the connection strength between the lug boss 3 and the base 2 can be enhanced, thus facilitating the stability of the placement of the main body 1 onto the base of a direct-insert type. Of course, the lug boss 3 may be fixed on the base 2 with various connection methods. For example, the lug boss 3 may be welded on the base 2, or bucked with the base 2. Furthermore, in some embodiments, the base 2 is provided with an upper surface and a lower surface, wherein the lug boss 3 is fixed on the upper surface of the base, while the lower surface of the base is configured for contacting with the surface of the table. As shown in FIG. 7, in this embodiment, a grid structure is formed in the lower surface. With the grid structure, the pressure from the upper surface is capable of being better transferred, and at the same time the friction between the lower surface and the surface of the table may be increased with the grid structure, thus facilitating the stability of the placement of the main body into the base of a direct-insert type. In some embodiments, the lower surface may also be for example in shape of a flat plane or the like.

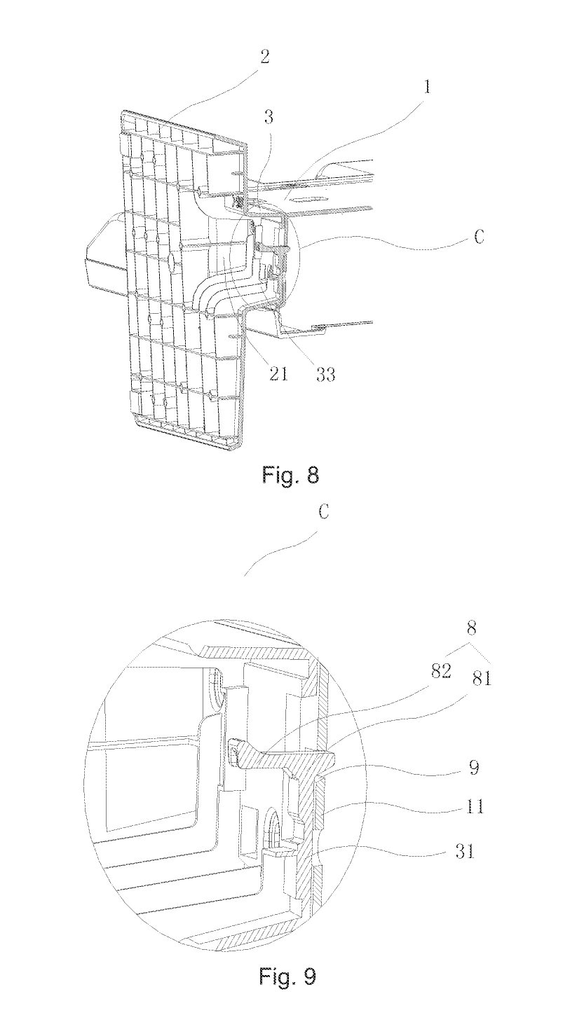

As shown in FIG. 6, the lug boss 3 is not limited to a specific shape, for example it may be in shape of a cuboid or a cube, etc. In this embodiment, the lug boss 3 is substantially in shape of a cuboid. Furthermore, the lug boss 3 includes a top surface 31 and a plurality of lateral surfaces 32 extending around the circumference of the top surface 31 in the same direction. As shown in FIG. 7 and FIG. 8, a cavity 33 is formed by the top surface 31 and the plurality of lateral surfaces 32. The number of the lateral surfaces 32 is four for example, wherein three of the lateral surfaces are curved surfaces, while the rest one is a flat plane. The angles of the cuboid lug boss 3 are rounded, so as to avoid accidently injury on human body caused by right angles. A height of the lug boss 3 is selected as required; preferably, the height of the lug boss 3 is between 2 cm to 10 cm, and more preferably, the height of the lug boss is between 3 cm to 6 cm. The appearance of the base of a direct-insert type may be improved by reducing the height of the lug boss 3. Advantageously, the number of the lug boss 3 is one. In some embodiments, a plurality of lug bosses 3, such as two or three lug bosses 3 or the like, may be provided. In one case, the plurality of lug bosses 3 may be linearly arranged on the base 2 with even intervals; in other cases, the lug bosses 3 may be arranged into a specific shape, such as a triangle; in this way, the stability may be improved. Certainly, when a plurality of lug bosses 3 are provided, the number and the position of the second engaging element 5 are correspondingly adjusted. Other configurations are similar to those in this embodiment.

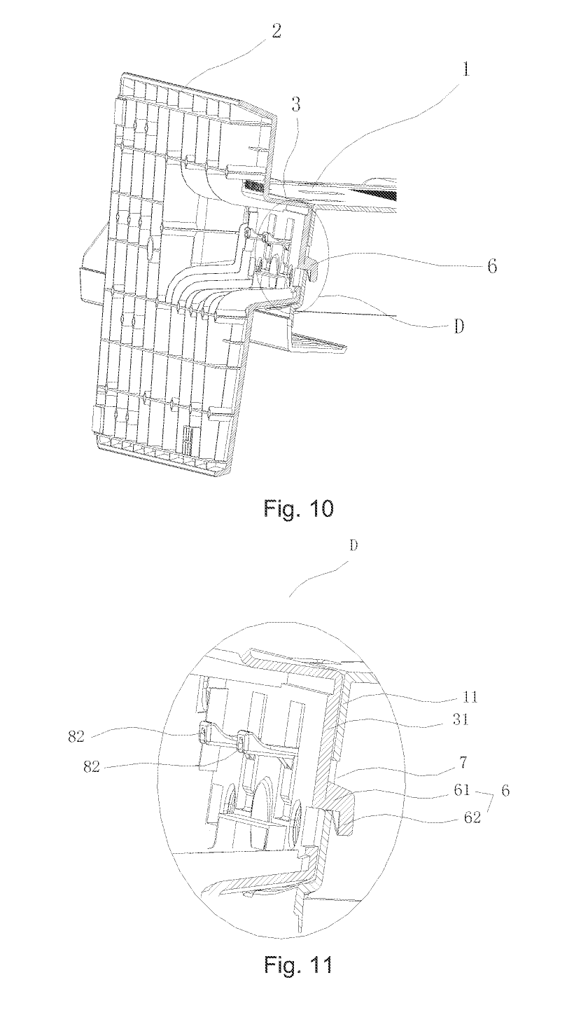

As shown in FIG. 6, the first engaging element 4 includes a buckle 6. As shown in FIG. 5, the second engaging element 5 includes a buckle slot 7. Referring to FIG. 10 and FIG. 11, the buckle 6 is inserted into the buckle slot 7 and is engaged with the buckle slot 7. As shown in FIG. 6, the buckle 6 is arranged on the top surface 31 of the lug boss 3, and the number of the buckle 6 is at least one. In this embodiment, the number of the buckle 6 is four, wherein, two buckles 6 are provided on one side of the top surface 31, and the other two buckles 6 are provided on the other side of the top surface 31. The buckles 6 are symmetrically distributed on both sides of the top surface 31, so as to increase the stability of the placement of the main body 1. In other embodiments, certainly, the number of the buckle 6 may also be one, two or more. The position of the buckle 6 is also not limited here. For example, the buckle may be located near the center of the top surface 31, or at the edge of the top surface 31. The shape, the number and the position of the buckle slot 7 should match with those of the buckle 6. In some embodiments, it is also possible that the first engaging element 4 includes the buckle slot 7, while the second engaging element 5 includes the buckle 6, i.e., the position of the buckle slot 7 and that of the buckle 6 are switched with each other. Other configurations are similar to those in this embodiment.

As shown in FIG. 11, the buckle 6 includes an abutting portion 61 arranged in the buckle slot 7 and an engaging portion 62 horizontally extending from an end of the abutting portion 61. The abutting portion 61 and the engaging portion 62 are fixedly connected to each other at an angle of for example 100° or 120°, etc. The abutting portion 61 runs through the buckle slot 7, while the engaging portion 62 is positioned in the inner side of the buckle slot 7 and abuts against the inner wall of the buckle slot 7. The abutting portion 61 is integrally formed with the engaging portion 62, while the buckle 6, the lug boss 3 and the base body 2 are integrally formed with each other.

As shown in FIG. 6, in this embodiment, a first positioning element 8 is also provided on the lug boss 3. As shown in FIG. 5, a first positioning slot 9 is correspondingly defined on the bottom of the main body 1. As shown in FIG. 8 and FIG. 9, the first positioning element 8 is inserted into the first positioning slot 9, so that the first positioning element 8 is sheathed in the first positioning slot 9. In some embodiments, it is also possible that no first positioning element 8 and the first positioning slot 9 are provided; instead, while the buckle 6 is engaged with the buckle slot 7, the buckle 6 may be further magnetically connected to the buckle slot 7. For example, the first inserting component may include an iron element, while the second inserting component may include a magnet, and the buckle 6 is magnetically connected to the buckle slot 7 by the iron element and the magnet. In a further embodiment, it may also be possible for the first positioning element 8 and the first positioning slot 9 to be magnetically connected to each other, i.e., the first positioning element 8 may be configured as a iron element, while the first positioning slot 9 may be configured as a magnet, or the first positioning element 8 may be configured as a magnet, while the first positioning slot 9 may be configured as a iron element. The first engaging element 4 and the second engaging element 8 are both arranged on the top surface 31. In this case, the base body 2, the lug boss 3, the first engaging element 4 and the first positioning element 8 are integrally formed with each other.

As shown in FIG. 6, the number of the first positioning element 8 is not limited here, for example, it may be one, two or five, etc. In this embodiment, two first positioning elements 8 are provided, which are located among the four buckles 6 and are symmetrically arranged. The location relationship between the first positioning element 8 and the buckle 6 is not limited to that mentioned above. In other words, for example, the buckle 6 may be located between the first positioning elements 8, or the buckle 6 and the first positioning element 8 are irregularly arranged.

As shown in FIG. 9, the first positioning element 8 includes a resilient inserting portion 81 positioned in the first positioning slot 9 and a pressing handle 82 extending along the resilient inserting portion 81 in the direction towards the through hole 21, wherein the pressing handle 82 is arranged in the cavity 3. The resilient inserting portion 81 is resilient, with the top end thereof inserted in the first positioning slot 9. With the application of the resilience generated by the resilient inserting portion 81, the resilient inserting portion 81 tightly abuts against two side walls of the first positioning slot 9 that are contacted with the resilient inserting portion 81. In some embodiments, it is also possible that no first positioning element 8 and the first positioning slot 9 are provided. Instead, the first engaging element 4 is directly connected to the second engaging element 5. Other configurations are similar to those in this embodiment.

As shown in FIG. 7 and FIG. 8, a through hole 21 communicated with the cavity 33 is defined on the base body 2. In this way, user operations may be facilitated. For example, when the disassembly is needed, one hand of a user may enter into the cavity 33 via the through hole 21, and press the pressing handle 82, so that the first positioning element 8 is separated from the first positioning slot 9, and the base body 2 is lifted upward at the same time, thus the buckle 6 may be separated from the buckle slot 7. Therefore, the base in this embodiment may be easily and conveniently removed from the main body 1.

In this embodiment, as shown in FIG. 5, it is preferable that a groove 10 adapted to the lug boss 3 is formed on the bottom of the main body 1, wherein the groove 10 includes a bottom wall 11, on which both the second engaging element 5 and the first positioning slot 9 are arranged. The depth of the groove 10 should not be too deep, in case that the entire appearance of the main body will be affected. Preferably, the depth of the groove 10 ranges from 0.5 cm to 3 cm, thus causing a less impact on the entire appearance of the main body 1. The shape of the groove 10 should be adapted to that of the top surface 31 of the lug boss 3, that is, the top surface 31 may exactly arranged in the groove 10. In this way, on one hand, the top surface 31 will be hided from the groove 10 so as to avoid being exposed, and thus the appearance will not be affected. On the other hand, the lug boss 3 may be wrapped by the lateral surfaces of the groove 10 which may limit the position of the lug boss 3, and the stability of the connection may be improved. The groove 10 is located on the bottom of the main body 1 so as to improve the appearance, in this way, the problem of lacking of aesthetics appearance because of the notch 97 defined on bottom of the back of the flat panel television 91 (the electronic device) may be solved. In some embodiments, it is also possible that no groove 10 is formed. Instead, the second engaging element 5 and the first positioning slot 9 are directly arranged on the bottom of the main body 1, wherein the bottom of the main body 1 is a flat plane. Other configurations are similar to those in this embodiment.

In some embodiments, a mounting hole may also be defined on the top surface 31, and correspondingly a screw hole is defined on the bottom wall 11, in such a way that the top surface 31 is fixed on the bottom wall 11 by sequentially inserting a fastener (for example a screw) into the mounting hole and the screw hole, thus facilitating the stability of the connection between the lug boss 3 and the main body 1.

During the assembly, the buckles 6 and the buckle slots 7 are aligned with one another, the base body 2 is pushed, so that the buckle 6 is engaged with the buckle slot 7. Then the first positioning element is inserted into the first positioning slot 9, and thus the assembly is finished. In this way, via the base of a direct-insert type, the main body may be put on a table, for example on a desk or a television cabinet, and thus the assembly of the electronic device is fast and easy.

However, when the disassembly is needed, one hand of the user may enter into the cavity 33 via the through hole 21, and press the pressing handle 82, so that the first positioning element 8 is separated from the first positioning slot 9, and the base body 2 is lifted upward at the same time, in such a way that the buckle 6 may be separated from the buckle slot 7. In this way, the base of a direct-insert type in this embodiment may be easily and conveniently removed from the main body 1.

### Embodiment 2

Embodiment 2 is substantially the same with embodiment 1, only distinguished in that the position of first positioning element 8 and that of the first positioning slot 9 are switched with each other, that is to say, a second positioning slot is provided on the lug boss 3, a second positioning element is correspondingly fixedly arranged on the bottom of the main body 1, and the second positioning element is inserted in the second positioning slot. The structure of the second positioning slot is the same as that of the first positioning slot 9 in the embodiment 1, and the structure of the second positioning element is also the same as that of the first positioning element 8 in the embodiment 1. Other configurations are the same as those in the embodiment 1, and will not be described in detail and more.

It should be understood that, one skilled in the art can make any improvements or modifications which don't depart from the scope of the spirit and the principle of the present application, and these improvements and modifications should be included within the scope of the present application.

1. An electronic device, comprising a main body and a base with which the main body is capable of seating upon a surface of a table, wherein the base includes a base body and a lug boss fixed on the base body; the lug boss is provided with a first inserting component, and a second inserting component adapted to the first inserting component is provided on the bottom of the main body; the first inserting component and the second inserting component are plugged into each other for connecting the main body to the base.

2. The electronic device according to claim 1, wherein the first inserting component includes a first engaging element, and the second inserting component includes a second engaging element; the first engaging element is engaged with the second engaging element.

3. The electronic device according to claim 2, wherein the first engaging element includes a buckle, and the second engaging element includes a buckle slot; the buckle is inserted into the buckle slot and is engaged with the buckle slot.

4. The electronic device according to claim 3, wherein the buckle includes an abutting portion arranged in the buckle slot and an engaging portion horizontally extending from an end of the abutting portion.

5. The electronic device according to claim 2, wherein the first inserting component further includes a first positioning element, the second inserting component includes a first positioning slot, and the first positioning element is sheathed in the first positioning slot.

6. The electronic device according to claim 2, wherein the first inserting component includes a second positioning slot, and the second inserting component includes a second positioning element; the second positioning element is sheathed in the second positioning slot.

7. The electronic device according to claim 5, wherein a groove adapted to the lug boss is formed on the bottom of the main body, and the groove includes a bottom wall, on which both the second engaging element and the first positioning slot are arranged.

8. The electronic device according to claim 5, wherein the lug boss includes a top surface and a plurality of lateral surfaces extending around a circumference of the top surface in the same direction, a cavity is formed by the top surface and the plurality of lateral surfaces, and the first engaging element and the first positioning element are arranged on the top surface.

9. The electronic device according to claim 8, wherein the base body, the lug boss, the first engaging element and the first positioning element are integrally formed with each other.

10. The electronic device according to claim 8, wherein a through hole communicated with the cavity is defined on the base body.

11. The electronic device according to claim 10, wherein the first positioning element includes a resilient inserting portion positioned in the first positioning slot and a pressing handle extending along the resilient inserting portion in the direction towards the through hole, wherein the pressing handle is arranged in the cavity.
